(19) United States
(12) Patent Application Publication
(10) Pub. No.: US 2025/0130294 A1
(43) Pub. Date: Apr. 24, 2025

(54) SENSOR DEVICES HAVING SEMICONDUCTOR SUBSTRATE TRENCHES, AND ASSOCIATED PRODUCTION METHODS

(71) Applicant: Infineon Technologies AG, Neubiberg (DE)

(72) Inventor: Horst THEUSS, Wenzenbach (DE)

(21) Appl. No.: 18/916,926

(22) Filed: Oct. 16, 2024

(30) Foreign Application Priority Data
Oct. 18, 2023 (DE) 102023128588.2

(51) Int. Cl. G01R 33/00; G01R 33/09

(52) U.S. Cl. CPC G01R 33/0047; G01R 33/098

(57) ABSTRACT

A sensor device contains a magnetic field sensor chip. The magnetic field sensor chip contains a semiconductor substrate having a first surface and a second surface opposite the first surface, a sensor element that is arranged at the first surface and is configured to detect a magnetic field present at the location of the sensor element, and at least one trench extending from at least one of the two surfaces into the semiconductor substrate. The sensor element is spaced laterally from the at least one trench.

### CROSS-REFERENCE TO RELATED APPLICATION

This application claims priority to Germany Patent Application No. 102023128588.2 filed on Oct. 18, 2023, the content of which is incorporated by reference herein in its entirety.

### TECHNICAL FIELD

The present disclosure relates to sensor devices having semiconductor substrate trenches and to methods for producing such sensor devices.

### BACKGROUND

Magnetic field sensors may be used in various technical applications. In one specific example, magnetic field sensors are used in miniaturized camera modules, as may be contained in smartphones, for example. Very recent technology in this field is based on actuator systems assembled from coils, magnets and sensors. Such systems are able to detect positions, distances and angles and use measured data to suitably move system components such as optical lenses, for example. In this context, target applications may include optical image stabilization, autofocus or optical zoom.

The magnetic field sensors used in this way may be sensitive to stress, that is to say their measurement signals may change undesirably due to mechanical loads that occur. In small hand-held devices, such as smartphones, for example, the magnetic field sensors that are used should be very thin, which may necessitate a thin housing, but also a sensor chip that is as thin as possible. However, a greatly reduced chip thickness may increase mechanical loads on the magnetic field sensor chip and the sensor elements integrated therein.

Manufacturers and developers of sensor devices are constantly striving to improve their products. It may in particular be of interest here to overcome the abovementioned problems and to provide sensor devices that achieve high measurement accuracies despite mechanical loads that occur. In addition, it may be desirable to provide suitable methods for producing such sensor devices.

### SUMMARY

Various aspects relate to a sensor device including a magnetic field sensor chip. The magnetic field sensor chip includes a semiconductor substrate having a first surface and a second surface opposite the first surface, a sensor element that is arranged at the first surface and is configured to detect a magnetic field present at the location of the sensor element, and at least one trench extending from at least one of the two surfaces into the semiconductor substrate. The sensor element is spaced laterally from the at least one trench.

Various aspects relate to a sensor device including a magnetic field sensor chip. The magnetic field sensor chip includes a semiconductor substrate having a first surface and a second surface opposite the first surface, and a sensor element that is arranged at one of the two surfaces and is configured to detect a magnetic field present at the location of the sensor element. The sensor device furthermore includes connecting elements that are arranged at the first surface and are configured to connect the sensor device to a carrier. The connecting elements define a region, located between them, of the first surface, wherein all of the connecting elements are arranged in the region defined thereby. The sensor element is arranged outside the region defined by the connecting elements in a plan view of the first surface.

### BRIEF DESCRIPTION OF THE DRAWINGS

Devices and methods according to the disclosure are explained in greater detail below with reference to drawings. Identical reference signs here may denote identical or similar components. The features of the various examples illustrated may be combined with one another, provided that they are not mutually exclusive, and/or they may be selectively omitted if they are not described as absolutely necessary.

FIGS. 1A to 1C schematically show a first side view, a bottom view, and a second side view of a sensor device 100, according to the disclosure.

FIGS. 2A to 2C schematically show side views of a sensor device 200, according to the disclosure.

FIG. 3 schematically shows a side view of a sensor device 300, according to the disclosure.

FIG. 4 schematically shows a side view of a sensor device 400, according to the disclosure.

FIGS. 5A to 5C schematically show a bottom view and two side views of a sensor device 500, according to the disclosure.

FIG. 6 schematically shows a side view of a sensor device 600, according to the disclosure.

FIGS. 7A and 7B schematically show a side view and a bottom view of a sensor device 700, according to the disclosure.

FIGS. 8A to 8C schematically show a first side view, a bottom view and a second side view of a sensor device 800, according to the disclosure.

FIG. 9 shows a flowchart of a method for producing a sensor device, according to the disclosure.

FIG. 10 shows a flowchart of a method for producing a sensor device, according to the disclosure.

### DETAILED DESCRIPTION

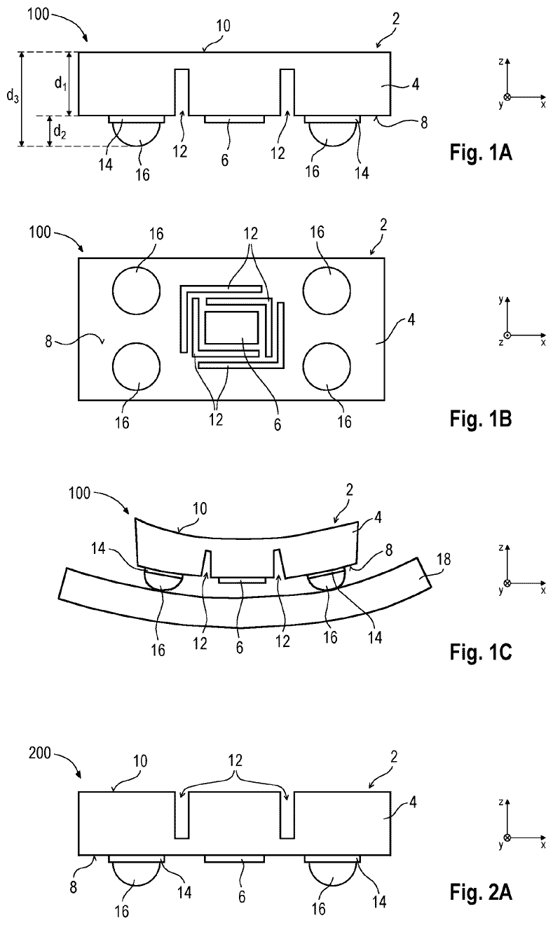

FIGS. 1A-1C illustrate an example of a sensor device 100. In some implementations, the sensor device 100 may contain a magnetic field sensor chip 2 having a semiconductor substrate 4 and at least one sensor element 6. The semiconductor substrate 4 may have a first surface 8, a second surface 10 opposite the first surface 8 and at least one trench 12 extending into the semiconductor substrate 4. The sensor device 100 may furthermore have one or more electrical contacts 14 and one or more connecting elements 16.

The magnetic field sensor chip 2 or the semiconductor substrate 4 may be made of any semiconductor material, in particular of silicon. The magnetic field sensor chip 2 or the semiconductor substrate 4 may be in particular a “bare die” that does not necessarily have to be arranged in a housing, but is able to be further processed and used without such a housing. In this description, the terms “die”, “chip”, “semiconductor die” and “semiconductor chip” may be used interchangeably.

In one example, the magnetic field sensor chip 2 may be a discrete semiconductor chip. A discrete semiconductor chip may correspond to a semiconductor component part that is configured to carry out an elementary electronic function and cannot be divided into separate components that are functional per se. In other words, a discrete semiconductor chip may correspond to a semiconductor component part that has only one basic function and not multiple complex functions, as may be the case for example with an integrated semiconductor circuit. In the present case, one basic function of the magnetic field sensor chip 2 may be that of detecting the magnetic field present at the location of the sensor element 6 and outputting a measurement signal based thereon.

Measured in the z-direction, a thickness d₁ of the semiconductor substrate may be smaller than about 110 micrometers or smaller than about 100 micrometers or smaller than about 90 micrometers. It may be seen from the bottom view of FIG. 1B that the footprint of the sensor device 100 may correspond to the footprint of the semiconductor substrate 4. The sensor device 100 may thus be a chip-scale package (CSP).

In the example shown, the sensor element 6 may be arranged on the first surface or the bottom 8 of the semiconductor substrate 4. The sensor element 6 may be configured to detect a magnetic field present at the location of the sensor element 6. More specifically, the sensor element 6 may be configured to detect one or more components of a magnetic field prevailing at the location of the sensor element 6. The respective sensitivity directions of the sensor element 6 may depend on the respective application. In one general example, the sensor element 6 may be sensitive in relation to each of the three spatial directions. In other words, the sensor element 6 may be configured to detect the x-, y- and z-components of a magnetic field present at the location of the sensor element 6. In further examples, the sensor element 6 may be sensitive in relation to only one or two spatial directions. Measurement signals based on the detected magnetic field components may be output from the sensor device 100 via the electrical contacts 14 and the connecting elements 16.

Generally speaking, the magnetic field sensor chip 2 or its sensor element 6 is not limited to a specific sensor technology. In the example shown, the sensor element 6 may in particular contain or correspond to a TMR (tunnel magnetoresistive) sensor element, that is to say the magnetic field sensor chip 2 may correspond to an (in particular linear) TMR sensor chip. In further examples, the sensor element 6 may also be configured differently, for example as an AMR (anisotropic magnetoresistive) sensor element or GMR (giant magnetoresistive) sensor element. In even further examples, the sensor element 6 may correspond to a Hall sensor element or a Fluxgate sensor element.

The sensor element 6 may be implemented for example as a resistor bridge (not shown), having for example four resistors. The resistors may for example be TMR resistors, which may be arranged in the form of a bridge circuit, such as for example a Wheatstone bridge. The sensor element 6 may be integrated into a circuit of the magnetic field sensor chip 2. In some examples, in addition and optionally, signal amplification, analog-to-digital conversion, digital signal processing and/or offset and temperature compensation may be carried out in such a circuit. In addition to the components of the sensor element 6, signal amplification components and/or analog-to-digital conversion components may or may not be considered as part of the sensor element 6.

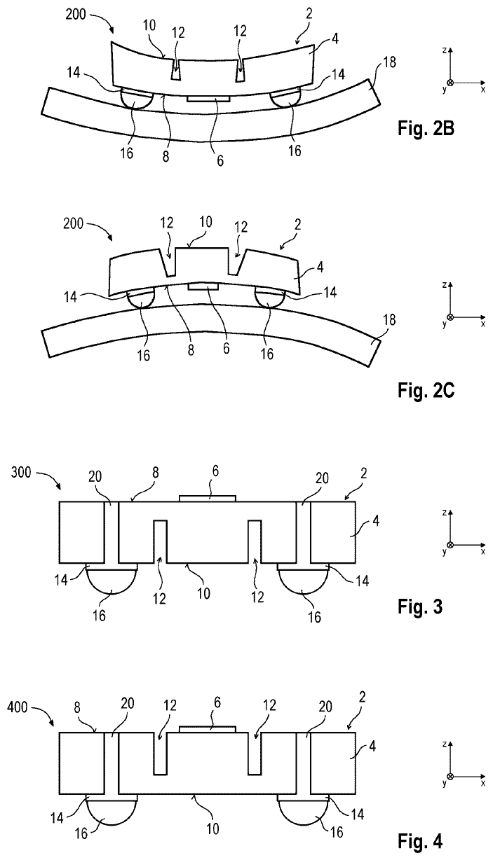

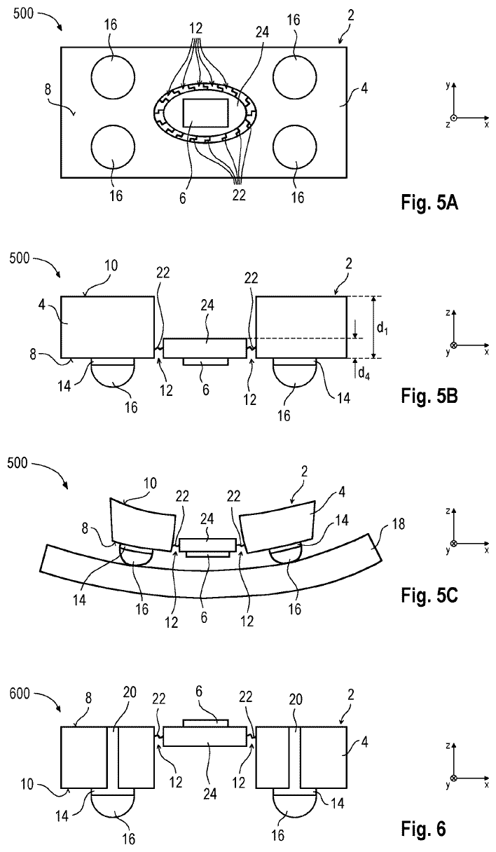

The at least one trench 12 may extend from at least one of the two surfaces 8 and 10 into the semiconductor substrate 4. In the example shown, the at least one trench 12 may extend from the bottom 8 of the semiconductor substrate 4 into the semiconductor substrate. As an alternative or in addition, the at least one trench 12 may extend from the top 10 of the semiconductor substrate 4 into the semiconductor substrate, as shown and described for example in FIGS. 2A-2C. The at least one trench 12 may extend at least half-way into the semiconductor substrate 4. In some examples, the at least one trench 12 may extend through the semiconductor substrate 4 all the way from the bottom 8 to the top 10, as shown and described for example in FIGS. 5A-5C. The at least one trench 12 may be produced using any suitable technique. In one example, the at least one trench 12 may be etched into the material of the semiconductor substrate 4. A deep-trench silicon etching process may be applied here, for example.

The sensor device 100 may be mounted on a carrier 18, which may for example be a printed circuit board (PCB). The components of the sensor device 100 and the carrier 18 may have different coefficients of thermal expansion. In the event of temperature fluctuations occurring during production and/or operation of the sensor device 100, this may cause mechanical stresses within the semiconductor substrate 4. These mechanical stresses may be transferred to the sensor element 6 and distort the measurement signals provided thereby. One example scenario in which such mechanical stresses may occur is shown and described in FIG. 1C.

The at least one trench 12 may be configured to at least partially decouple the sensor element 6 from mechanical stresses occurring in the semiconductor substrate 4. In this context, the at least one trench 12 may also be referred to as a stress decoupling trench. A position, number and shape of the at least one trench 12 may in principle be chosen as desired, as long as the use of the at least one trench 12 makes it possible to provide the desired mechanical decoupling of the sensor element 6.

In the example shown, the sensor device 100 may have an example number of four trenches 12, as illustrated in the bottom view of FIG. 1B (for the sake of simplicity, only two trenches 12 are shown in the side views of FIGS. 1A and 1C). In further examples, the number of trenches 12 may also be chosen differently. In the bottom view of FIG. 1B, the trenches 12 may for example be L-shaped and surround the sensor element 6. In further examples, the trenches 12 may have a different design and extend completely or at least partially around the sensor element 6 when viewed in the z-direction. A trench 12 may in this case for example form the shape of one or more straight lines, a circle or part thereof, an ellipse or part thereof, a square or part thereof, a rectangle or part thereof, etc. The trenches 12 do not necessarily have to have a uniform design, but may also differ in terms of their shapes.

The trenches 12 may define a boundary between an inner region of the semiconductor substrate 4 and an edge region of the semiconductor substrate 4, as may be seen in the bottom view of FIG. 1B. The sensor element 6 may in this case be arranged in particular in the inner region of the semiconductor substrate 4. The sensor element 6 may be spaced laterally from the trenches 12 and vice versa. In other words, the sensor element 6 and the trenches 12 may be offset laterally from one another. In this case, the trenches 12 may be arranged in particular between the sensor element 6 and the connecting elements 16.

In the example shown, the at least one connecting element 16 may be arranged on the bottom 8 of the semiconductor substrate 4. The sensor device 100 may have an example number of four connecting elements 16, wherein the sensor element 6 may be positioned between the connecting elements 16. In the case shown, the four connecting elements 16 may be arranged, by way of example, at the vertices of a rectangle, and the sensor element 6 may be positioned at the geometric center of gravity of this rectangle.

The connecting elements 16 may be configured to electrically and/or mechanically connect the sensor device 100 to the carrier 18. The carrier 18 may or may not be considered as part of the sensor device 100. In the example shown, the connecting elements 16 may be solder balls or solder deposits, such that the sensor device 100 is able to be connected to the carrier 18 by a soldering operation. In further examples, the connecting elements 16 may also be configured differently, for example as copper pillar bumps, which may each have a copper column having a cap made of solder material arranged thereon.

The connecting elements 16 may be electrically connected to chip-internal electrical structures, and in particular to the sensor element 6, via the electrical contacts 14. Measurement signals provided by the sensor element 6 may be output from the sensor device 100 via the connecting elements 16, and furthermore provided to other electronic components (not shown) via the carrier 18. The electrical contacts 14 may for example be underbump metallizations.

A common thickness d₂ of the connecting elements 16 and of the electrical contacts 14 may be in a range of about 40 micrometers to about 60 micrometers, measured in the z-direction. A typical value of the thickness d₂ may be about 50 micrometers, for example. With the thicknesses d₁, already mentioned above, of the semiconductor substrate 4, a total thickness d₃, measured in the z-direction, of the sensor device 100 may thus for example be smaller than about 160 micrometers or smaller than about 150 micrometers or smaller than about 140 micrometers.

The sensor device 100, due to its small thickness d₃, is able to be used in a particularly space-saving manner, and in particular in small applications. In one example, the sensor device 100 may be used in miniaturized camera modules, as may be contained in smartphones, for example. Such camera modules may be based on actuator systems that may be assembled from coils, magnets and sensors. The actuator systems are able to detect positions, distances and angles and use measured data to suitably move system components such as optical lenses, for example. In this context, the magnetic field sensor chip 2 may be configured to be used in one or more optical applications of the camera module, for example in at least one of an optical image stabilization application, an autofocus application, an optical zoom application, etc. The magnetic field sensor chip 2 is able to detect a magnetic field present at the location of the sensor element 6. Based on the measurement signals provided by the magnetic field sensor chip 2, it is then possible to determine positions, distances and angles required by the application.

As already mentioned above, forming the at least one trench 12 in the semiconductor substrate 4 makes it possible to at least partially decouple the sensor element 6 from mechanical stresses occurring in the semiconductor substrate 4. In this context, FIG. 1C shows one example scenario in which such mechanical decoupling is able to prevent measurement signals provided by the magnetic field sensor chip 2 from being distorted.

In the scenario shown, a comparatively high temperature may prevail, for example. The carrier 18 and the semiconductor substrate 4 may warp, for example in convex fashion, due to different coefficients of thermal expansion of the components shown. In FIG. 1C, such warping is illustrated in exaggerated form for the sake of clarification. The trenches 12 are able to give the semiconductor substrate 4 greater flexibility, such that mechanical loads acting on the sensor element 6 are able to be reduced compared to a semiconductor substrate without stress decoupling trenches.

The sensor device 200 of FIGS. 2A-2C may have some or all of the features of the sensor device 100 of FIGS. 1A-1C. In the example shown, the at least one trench 12 may extend from the second surface 10 or the top of the semiconductor substrate 4 into the semiconductor substrate 4. The at least one trench 12 may thus extend into the surface of the semiconductor substrate 4, this surface being opposite the active surface of the semiconductor substrate 4 comprising the sensor element 6. This makes it possible to simplify production of the sensor device 200, since formation of the at least one trench 12 and machining of the active surface of the semiconductor substrate 4 may be carried out separately. In this case, the at least one trench 12 may preferably be formed following completion of the active surface. The at least one trench 12 may extend into the bulk semiconductor material of the semiconductor substrate 4. The at least one trench 12 of the sensor device 200 may be formed for example as shown in FIG. 1B, that is to say in the form of multiple L-shaped trenches 12, viewed in the z-direction.

FIGS. 2B and 2C show two example scenarios in which the sensor element 6 is able to be decoupled from mechanical stresses occurring in the semiconductor substrate 4 by using the trenches 12. Similarly to FIG. 1C, a comparatively high temperature may prevail in the scenario of FIG. 2B, and the carrier 18 and the semiconductor substrate 4 may warp, for example in convex fashion. The trenches 12 are able to give the semiconductor substrate 4 greater flexibility, such that the sensor element 6 is able to be relieved from mechanical stress. A comparatively low temperature may prevail in the scenario of FIG. 2C, and the carrier 18 and the semiconductor substrate 4 may warp, for example in concave fashion. In this scenario too, the trenches 12 are able to give the semiconductor substrate 4 greater flexibility, such that the sensor element 6 is able to be relieved from mechanical stress.

The sensor device 300 of FIG. 3 may have some or all of the features of sensor devices described above. In the example shown, the sensor element 6 and the connecting elements 16 may be arranged at opposite surfaces of the semiconductor substrate 4. The sensor element 6 may in this case be arranged at the first surface 8 or the top of the semiconductor substrate 4, and the connecting elements 16 may be arranged at the second surface 10 or the bottom of the semiconductor substrate 4.

The sensor device 300 may have at least one electrical plated through-hole 20 extending through the semiconductor substrate 4 from the top 8 to the bottom 10, which plated through-hole may be configured to electrically connect the sensor element 6 to at least one of the connecting elements 16 or an associated electrical contact 14. In the example shown, the electrical plated through-holes 20 may be vertically extending through silicon vias (TSVs). A respective electrical plated through-hole 20 may be electrically connected to the corresponding connecting element 16 at the bottom 10 and to the sensor element 6 at the top 8. For the sake of simplicity, the electrical connections between the sensor element 6 and the electrical plated through-holes 20 are not illustrated explicitly in FIG. 3.

In an arrangement of the sensor device 300 on a printed circuit board, the sensor element 6 may face away from the printed circuit board. This may enable the smallest possible distance of the sensor element 6 from a magnet, which may likewise be positioned above the printed circuit board. Such a magnet may for example be configured to generate a magnetic field to be measured. In other words, the magnet may correspond to an encoder structure that, in the example shown, may be arranged as close as possible to the sensor element 6. For example, an encoder magnet may be mechanically coupled to a lens whose position is to be determined with the aid of the sensor device 300.

The sensor device 400 of FIG. 4 may have some or all of the features of sensor devices described above, in particular of the sensor device 300 of FIG. 3. In the example shown, the at least one trench 12 may extend from the top 8 of the semiconductor substrate 4 into the semiconductor substrate 4. The at least one trench 12 may thus extend into the surface of the semiconductor substrate 4, this surface being opposite the active surface of the semiconductor substrate 4 comprising the sensor element 6.

The sensor device 500 of FIGS. 5A-5C may have some or all of the features of sensor devices described above. In the example shown, the sensor device 500 may have a multiplicity of trenches 12, which may each extend through the semiconductor substrate 4 from the first surface 8 all the way to the second surface 10. A multiplicity of spring structures 22 formed from the material of the semiconductor substrate 4 may be formed between the trenches 12. A respective spring structure 22 may in this case be formed between two adjacent trenches 12. For example, a number of trenches 12 or of spring structures 22 formed between the trenches 12 may be greater than about 10, or greater than about 15, or greater than about 20. The spring structures 22 may in particular have a curved shape (for example wave-shaped, s-shaped, u-shaped, v-shaped, etc.), making it possible to give them a desired elasticity. The spring structures 22 may be configured to be able to be deformed elastically (reversibly).

In one example, the trenches 12 may be produced by an etching process, wherein the spring structures 22 may remain as residual parts of the bulk semiconductor material (for example bulk silicon) following the etching. Producing the trenches 12 makes it possible to form a region 24 of the semiconductor substrate 4 that is suspended on the spring structures 22. The sensor element 6 may be arranged in this suspended region 24. Since the spring structures 22 are clastic and provide elastic suspension of the region 24, the region 24, and thus the sensor element 6, are able to be at least partially decoupled from mechanical stresses occurring in the semiconductor substrate 4. Using the trenches 12 or the suspended region 24 thus makes it possible to prevent or at least reduce distortion of measurement signals from the sensor device 500.

A thickness d₄, measured in the z-direction, of the semiconductor substrate 4 in a region above the sensor element 6 may be smaller than a thickness d₁, measured in the z-direction, of the semiconductor substrate 4 in a region next to the sensor element 6. In the example shown, a thickness d₄ of the suspended region 24 may in particular be smaller than a thickness d₁ of the semiconductor substrate 4 at locations outside the suspended region 24. The smaller the thickness d₄ of the suspended region 24, the better the sensor element 6 is able to be mechanically decoupled from mechanical loads within the semiconductor substrate 4.

The sensor device 600 of FIG. 6 may have some or all of the features of sensor devices described above, in particular of the sensor devices 300 and 500 of FIGS. 3 and 5. In the example shown, the sensor element 6 and the connecting elements 16 may be arranged at opposite surfaces of the semiconductor substrate 4. The sensor element 6 may in this case be arranged at the top or the first surface 8 of the semiconductor substrate 4, while the connecting elements 16 may be arranged at the bottom or the second surface 10 of the semiconductor substrate 4.

Similarly to the example of FIG. 3, the sensor device 600 may have at least one electrical plated through-hole 20 extending through the semiconductor substrate 4 from the top 8 to the bottom 10, which plated through-hole may be configured to electrically connect the sensor element 6 to at least one of the connecting elements 16 or an associated electrical contact 14. Similarly to the example of FIGS. 5A-5C, the sensor device 600 may have spring structures 22 formed in the semiconductor substrate 4 and a region 24 of the semiconductor substrate 4 that is suspended on the spring structures 22, wherein the sensor element 6 may be arranged in the region 24 suspended on the spring structures 22.

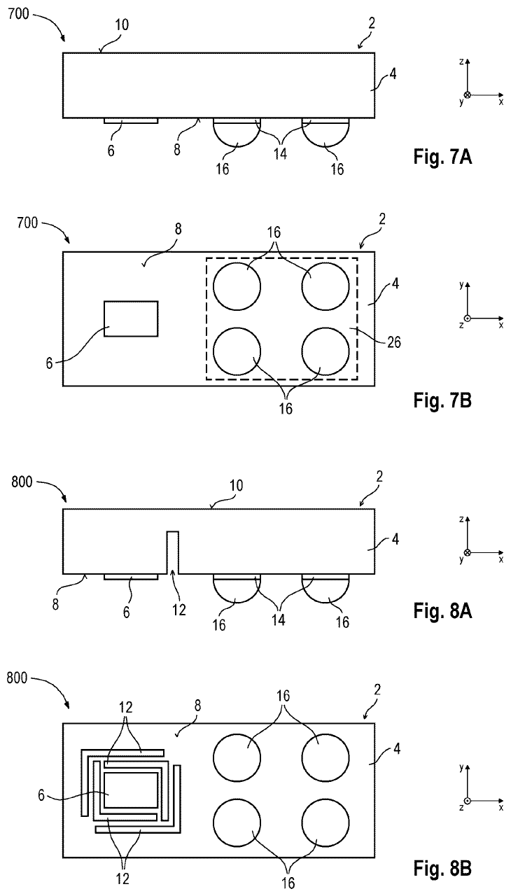

The sensor device 700 of FIGS. 7A and 7B may contain a magnetic field sensor chip 2 having a semiconductor substrate 4, which may have a first surface 8 and a second surface 10 opposite the first surface 8. At least one sensor element 6 may be arranged at one of the two surfaces 8 and 10 and may be configured to detect a magnetic field present at the location of the sensor element 6. Connecting elements 16 may furthermore be arranged at the first surface 8 and may be configured to connect the sensor device 700 to a carrier (not shown). The components of the sensor device 700 may be similar to corresponding components of sensor devices described above and have similar properties.

In the example shown, both the sensor element 6 and the connecting elements 16 may be arranged at the bottom 8 of the semiconductor substrate 4. In further examples, the sensor element 6 and the connecting elements 16 may be arranged on opposite surfaces of the semiconductor substrate 4. In the case shown, the sensor device 700 may have an example number of four connecting elements 16. The connecting elements 16 may define a region 26, located between them, of the first surface 8. The region 26 may be a single contiguous region. In the example shown, the region 26 may correspond to the surface of a rectangle at whose vertices the connecting elements 16 may be arranged. The rectangle is illustrated by a dashed line in the bottom view of FIG. 7B.

All of the connecting elements 16 may be arranged in the region 26 defined thereby. In contrast thereto, the sensor element 6 may be arranged outside the region 26. The sensor element 6 may be arranged, in particular, in an edge region (or at one or more edges) of the first surface 8, wherein all of the connecting elements 16 may be arranged outside this edge region. It may in particular be seen from the side view of FIG. 7A that this edge region may overhang the connecting elements 16 or protrude beyond the region 26 defined by the connecting elements 16.

The sensor device 700 may be connected to a carrier (not shown) via the connecting elements 16. As described for example in connection with FIG. 1C, the carrier and the semiconductor substrate 4 may warp during production or operation of the sensor device 700. The mechanical stresses occurring here in the semiconductor substrate 4 may occur predominantly in the region of the connecting elements 16 or in the region 26 defined thereby. Since the sensor element 6 is arranged outside the region 26, the sensor element 6 is able to be at least partially decoupled from the mechanical stresses within the semiconductor substrate 4.

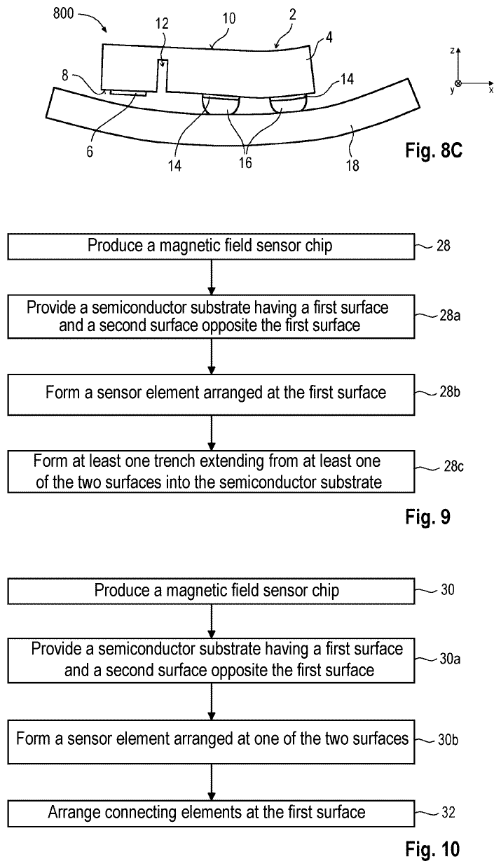

The sensor device 800 of FIGS. 8A-8C may have some or all of the features of sensor devices described above, in particular of the sensor devices 100 and 700 of FIGS. 1 and 7. Similarly to the example of FIGS. 7A and 7B, in the sensor device 800, the sensor element 6 may be arranged outside a region 26 defined by the connecting elements 16. Similarly to the example of FIGS. 1A-1C, the sensor device 800 may have at least one trench 12 extending from at least one of the two surfaces 8 and 10 into the semiconductor substrate 4, wherein the sensor element 6 is spaced laterally from the at least one trench 12.

In the example shown, the at least one trench 12 may extend from the active bottom 8 into the semiconductor substrate 4. It is thus possible, in the sensor device 800, to provide dual decoupling of the sensor element 6 from mechanical stresses occurring in the semiconductor substrate 4. This is achieved by positioning the sensor element 6 outside the region 26 defined by the connecting elements 16, on the one hand, and by the at least one trench 12 arranged laterally to the sensor element 6, on the other hand.

FIGS. 9 and 10 show flowcharts of methods for producing sensor devices according to the disclosure. The methods of FIGS. 9 and 10 are described in a general form in order to specify aspects of the present disclosure in qualitative terms. The methods may comprise further aspects. By way of example, the methods may be expanded to include any of the aspects described herein in connection with other examples. In particular, the methods may be used to produce sensor devices described above according to the disclosure.

FIG. 9 shows a first method for producing a sensor device according to the disclosure. The method of FIG. 9 may be used for example to produce the sensor devices of FIGS. 1A through 6. In an action 28, a magnetic field sensor chip may be produced. The production of the magnetic field sensor chip may include an action 28a of providing a semiconductor substrate having a first surface and a second surface opposite the first surface. The production of the magnetic field sensor chip may furthermore include an action 28b of forming a sensor element that is arranged at the first surface and is configured to detect a magnetic field present at the location of the sensor element. The production of the magnetic field sensor chip may furthermore include an action 28c of forming at least one trench extending from at least one of the two surfaces into the semiconductor substrate. The sensor element may be spaced laterally from the at least one trench.

FIG. 10 shows a second method for producing a sensor device according to the disclosure. The method of FIG. 10 may be used for example to produce the sensor device of FIGS. 7A and 7B and/or the sensor device of FIGS. 8A-8C. In an action 30, a magnetic field sensor chip may be produced. The production of the magnetic field sensor chip may include an action 30a of providing a semiconductor substrate having a first surface and a second surface opposite the first surface. The production of the magnetic field sensor chip may furthermore include an action 30b of forming a sensor element that is arranged at one of the two surfaces and is configured to detect a magnetic field present at the location of the sensor element. In an action 32, connecting elements may be arranged at the first surface, these being configured to connect the sensor device to a carrier. The connecting elements may define a region, located between them, of the first surface, wherein all of the connecting elements may be arranged in the region defined thereby. The sensor element may be arranged outside the region defined by the connecting elements in a plan view of the first surface.

### ASPECTS

Sensor devices according to the disclosure and associated production methods are described below based on aspects.

Aspect 1 is a sensor device, comprising: a magnetic field sensor chip, comprising: a semiconductor substrate having a first surface and a second surface opposite the first surface, a sensor element that is arranged at the first surface and is configured to detect a magnetic field present at the location of the sensor element, and at least one trench extending from at least one of the two surfaces into the semiconductor substrate, wherein the sensor element is spaced laterally from the at least one trench.

Aspect 2 is a sensor device according to Aspect 1, wherein the at least one trench is configured to at least partially decouple the sensor element from mechanical stresses occurring in the semiconductor substrate.

Aspect 3 is a sensor device according to Aspect 1 or 2, wherein the at least one trench defines a boundary between an inner region of the semiconductor substrate and an edge region of the semiconductor substrate, wherein the sensor element is arranged in the inner region of the semiconductor substrate.

Aspect 4 is a sensor device according to one of the preceding Aspects, wherein the at least one trench extends from the first surface into the semiconductor substrate.

Aspect 5 is a sensor device according to one of Aspects 1 to 3, wherein the at least one trench extends from the second surface into the semiconductor substrate.

Aspect 6 is a sensor device according to one of the preceding Aspects, wherein the at least one trench extends at least half-way into the semiconductor substrate.

Aspect 7 is a sensor device according to one of the preceding Aspects, wherein the at least one trench is L-shaped in a plan view of the first surface.

Aspect 8 is a sensor device according to one of the preceding Aspects, wherein the at least one trench extends through the semiconductor substrate all the way from the first surface to the second surface.

Aspect 9 is a sensor device according to Aspect 8, wherein the magnetic field sensor chip furthermore comprises: spring structures formed between a plurality of trenches of the at least one trench and formed from the material of the semiconductor substrate, and a region of the semiconductor substrate that is suspended on the spring structures, wherein the sensor element is arranged in the region suspended on the spring structures.

Aspect 10 is a sensor device according to one of the preceding Aspects, wherein a thickness of the semiconductor substrate in a region above the sensor element is smaller than a thickness of the semiconductor substrate in a region next to the sensor element.

Aspect 11 is a sensor device according to one of the preceding Aspects, furthermore comprising: at least one connecting element that is configured to connect the sensor device to a carrier, wherein the at least one connecting element is arranged at the first surface of the semiconductor substrate.

Aspect 12 is a sensor device according to one of Aspects 1 to 10, furthermore comprising: at least one connecting element that is configured to connect the sensor device to a carrier, wherein the at least one connecting element is arranged at the second surface of the semiconductor substrate.

Aspect 13 is a sensor device according to Aspect 12, wherein the magnetic field sensor chip furthermore comprises: at least one electrical plated through-hole extending through the semiconductor substrate from the first surface to the second surface, which plated through-hole is configured to connect the sensor element to the at least one connecting element.

Aspect 14 is a sensor device according to one of the preceding Aspects, wherein the sensor element comprises a TMR sensor element.

Aspect 15 is a sensor device according to one of the preceding Aspects, wherein the sensor device is a chip-scale package.

Aspect 16 is a sensor device according to one of the preceding Aspects, wherein: a thickness of the semiconductor substrate is smaller than 110 micrometers, and/or a thickness of the sensor device is smaller than 160 micrometers.

Aspect 17 is a sensor device according to one of the preceding Aspects, wherein the magnetic field sensor chip is a discrete semiconductor chip.

Aspect 18 is a sensor device, comprising: a magnetic field sensor chip, comprising: a semiconductor substrate having a first surface and a second surface opposite the first surface, and a sensor element that is arranged at one of the two surfaces and is configured to detect a magnetic field present at the location of the sensor element; and connecting elements that are arranged at the first surface and are configured to connect the sensor device to a carrier, wherein the connecting elements define a region, located between them, of the first surface, wherein all of the connecting elements are arranged in the region defined thereby, wherein the sensor element is arranged outside the region defined by the connecting elements in a plan view of the first surface.

Aspect 19 is a sensor device according to Aspect 18, wherein the sensor element is arranged at the first surface of the semiconductor substrate.

Aspect 20 is a sensor device according to Aspect 19, wherein the sensor element is arranged in an edge region of the first surface, wherein all of the connecting elements are arranged outside the edge region.

Aspect 21 is a sensor device according to Aspect 19, wherein the sensor element is arranged at the second surface of the semiconductor substrate.

Aspect 22 is a sensor device according to one of Aspects 18 to 21, wherein the magnetic field sensor chip furthermore comprises: at least one trench extending from at least one of the two surfaces into the semiconductor substrate, wherein the sensor element is spaced laterally from the at least one trench.

Although specific implementations have been illustrated and described herein, it is obvious to a person of average skill in the art that a multiplicity of alternative and/or equivalent implementations may replace the specific implementations shown and described, without departing from the scope of the present disclosure. This application is intended to cover all adaptations or variations of the specific implementations discussed herein. Therefore, the intention is for this disclosure to be restricted only by the claims and the equivalents thereof.

1. A sensor device, comprising:
a magnetic field sensor chip, comprising:
a semiconductor substrate having a first surface and a second surface opposite the first surface;
a sensor element that is arranged at the first surface and is configured to detect a magnetic field present at a location of the sensor element; and
at least one trench extending from at least one of the first surface or the second surface into the semiconductor substrate, wherein the sensor element is spaced laterally from the at least one trench.

2. The sensor device as claimed in claim 1, wherein the at least one trench is configured to at least partially decouple the sensor element from mechanical stresses occurring in the semiconductor substrate.

3. The sensor device as claimed in claim 1, wherein the at least one trench defines a boundary between an inner region of the semiconductor substrate and an edge region of the semiconductor substrate, and
wherein the sensor element is arranged in the inner region of the semiconductor substrate.

4. The sensor device as claimed in claim 1, wherein the at least one trench extends from the first surface into the semiconductor substrate.

5. The sensor device as claimed in claim 1, wherein the at least one trench extends from the second surface into the semiconductor substrate.

6. The sensor device as claimed in claim 1, wherein the at least one trench extends at least half-way into the semiconductor substrate.

7. The sensor device as claimed in claim 1, wherein the at least one trench is L-shaped in a plan view of the first surface.

8. The sensor device as claimed in claim 1, wherein the at least one trench extends from the first surface, through the semiconductor substrate, and to the second surface.

9. The sensor device as claimed in claim 8, wherein the magnetic field sensor chip further comprises:
spring structures formed between a plurality of trenches, wherein the plurality of trenches includes the at least one trench, wherein the spring structures are formed from a material of the semiconductor substrate, wherein a region of the semiconductor substrate is suspended on the spring structures, and wherein the sensor element is arranged in the region of the substrate that is suspended on the spring structures.

10. The sensor device as claimed in claim 1, wherein a thickness of the semiconductor substrate in a region above the sensor element is smaller than a thickness of the semiconductor substrate in a region next to the sensor element.

11. The sensor device as claimed in claim 1, further comprising:
at least one connecting element that is configured to connect the sensor device to a carrier, wherein the at least one connecting element is arranged at the first surface of the semiconductor substrate.

12. The sensor device as claimed in claim 1, further comprising:
at least one connecting element that is configured to connect the sensor device to a carrier, wherein the at least one connecting element is arranged at the second surface of the semiconductor substrate.

13. The sensor device as claimed in claim 12, wherein the magnetic field sensor chip further comprises:
at least one electrical plated through-hole extending through the semiconductor substrate from the first surface to the second surface, wherein the at least one electrical plated through-hole is configured to connect the sensor element to the at least one connecting element.

14. The sensor device as claimed in claim 1, wherein the sensor element comprises a tunnel magnetoresistive (TMR) sensor element.

15. The sensor device as claimed in claim 1, wherein the sensor device is a chip-scale package.

16. (canceled)

17. The sensor device as claimed in claim 1, wherein the magnetic field sensor chip is a discrete semiconductor chip.

18. A sensor device, comprising:
a magnetic field sensor chip, comprising:
a semiconductor substrate having a first surface and a second surface opposite the first surface; and
a sensor element that is arranged at one of the first surface or the second surface and is configured to detect a magnetic field present at a location of the sensor element; and
connecting elements that are arranged at the first surface and are configured to connect the sensor device to a carrier,
wherein the connecting elements define a region, located between the connecting elements, of the first surface,
wherein all of the connecting elements are arranged in the region defined thereby, and
wherein the sensor element is arranged outside the region defined by the connecting elements in a plan view of the first surface.

19. The sensor device as claimed in claim 18, wherein the sensor element is arranged in an edge region of the first surface of the semiconductor substrate, and wherein all of the connecting elements are arranged outside of the edge region.

20. (canceled)

21. The sensor device as claimed in claim 19, wherein the sensor element is arranged at the second surface of the semiconductor substrate.

22. The sensor device as claimed in claim 18, wherein the magnetic field sensor chip further comprises:
at least one trench extending from at least one of the first surface or the second surface into the semiconductor substrate, wherein the sensor element is spaced laterally from the at least one trench.
